(19) United States
(12) Patent Application Publication
(10) Pub. No.: US 2019/0316252 A1
(43) Pub. Date: Oct. 17, 2019

(54) HIGH THROUGHPUT CONTINUOUS OPERATION REACTOR SYSTEM

(71) Applicant: DURALAR TECHNOLOGIES, LLC, Tucson, AZ (US)

(72) Inventors: Andrew Tudhope, Tucson, AZ (US); Marion D. McEuen, Tucson, AZ (US); Jeffrey F. Vogler, Tucson, AZ (US); Thomas B. Casserly, Tucson, AZ (US)

(21) Appl. No.: 16/343,159

(22) PCT Filed: Oct. 18, 2017
(86) PCT No.: PCT/US17/57222

§ 371 Date: Apr. 18, 2019

Related U.S. Application Data
(60) Provisional application No. 62/409,793, filed on Oct. 18, 2016.

(51) Int. Cl. C23C 14/56; C23C 16/54

(52) U.S. Cl. CPC C23C 14/566; C23C 16/54; C23C 14/568

(57) ABSTRACT

A modular, offset In-line vacuum processing system is disclosed. The system comprises a plurality of independently operable process chambers each configured to accommodate a given number of carriers, where each carrier may hold a set of independently biased substrates. Further, each process chamber may be configured to execute one or more steps in one or more processes performed on each set of substrates. A plurality of Independently operable transfer chambers may be configured to transfer each carrier to and from process chambers for completing each step in the one or more processes. As a result, the system is able to: simultaneously coat the sets of substrates via a designated coating process (i.e., unique to each set of carriers); obtain a set of desired coating properties for each set of parts; perform processes having varying process step lengths; coat parts of multiple geometries; shut down individual chambers without interrupting production capacity.

### CROSS REFERENCE

This application claims priority to U.S. Patent Application No. 62/409,793, filed Oct. 18, 2016, the specification(s) of which is/are incorporated herein in their en by reference.

### FIELD OF THE INVENTION

The present invention relates to in-line vacuum processing systems, more specifically, to an offset in-line vacuum process system that is modular and configurable and that allows for a high throughput production capacity.

### BACKGROUND OF THE INVENTION

Most high-volume physical vapor deposition (“PVD”) and plasma chemical vapor deposition (“PECVD”) systems are considered high-volume because of the high production capacity of a single batch deposition run. The technology utilized in these high-volume systems is the same as that in their lower volume counterparts; the limits of pumping, power supplies, or targets are simply scaled to accommodate the high-volume. Batch deposition systems typically spend a large percentage of their available lifetime in (1) evacuating the system to base pressure, (2) heating the system, or (3) cooling the system. During these steps, productivity is zero and expensive power supplies and control equipment comprising these systems is underutilized. Batch systems typically spend another large portion of their lifetime unavailable due to system preventative (or unscheduled) maintenance. Some of these high-volume deposition systems may be categorized as continuous (or semi-continuous) systems that utilize evaporative techniques (e.g., thermal or arc) to metalize parts as they pass through one or multiple deposition zones. These systems lack the ability to independently bias the parts being coated. This limitation results in a lack of control of coating properties and an inability to accommodate multiple geometries of the parts being coated. Moreover, these systems are only able to perform one coating process at a time and cannot accommodate processes that vary in process step length. Additionally, any preventative or repair maintenance requires shutting off production for the entire system, which causes long delays in production and creates large amounts of scrap (every component currently in the line). The present disclosure features modular, configurable systems that address the aforementioned limitations, while maintaining a consistent production capacity even when preventative and repair maintenance are required.

Any feature or combination of features described herein are included within the scope of the present invention provided that the features included in any such combination are not mutually inconsistent as will be apparent from the context, this specification, and the knowledge of one of ordinary skill in the art. Additional advantages and aspects of the present invention are apparent in the following detailed description and claims.

### SUMMARY OF THE INVENTION

The present invention features an offset, in-line vacuum processing system. In some embodiments, the system comprises a plurality of process chambers and a transfer station comprising a plurality of independently operable transfer chambers. In other embodiments, each process chamber is configured to accommodate a given number of carriers that each holds a set of substrates. In an embodiment, each set of substrates is independently biased. In another embodiment, each process chamber is independently operable, held at vacuum pressure under independent pressure control, and configured to execute one or more steps in one or more processes performed on each set of substrates.

In further embodiments, the transfer station comprises a plurality of independently operable transfer chambers that are collectively pressure controlled at vacuum pressure. In one embodiment, each transfer chamber is operatively connected to one or more other transfer chambers and to one or more process chambers.

Consistent with previous embodiments, one or more carriers are initially loaded into a first transfer chamber. Each carrier may be routed through its own designated sequence of process chambers for performing a designated process, of the one or more processes. Further, the plurality of transfer chambers may be configured to transfer each carrier to and from each process chamber in the assigned designated sequence of process chambers. In exemplary embodiments, each set of substrates is independently biased; thus, each designated process may be individually tailored for a given set of carriers. The system is therefore able to uniquely and independently process each set of substrates.

As previously discussed, existing high-volume systems lack the ability to independently bias the parts being coated, resulting in a lack of control of coating properties and an inability to accommodate multiple geometries of the parts being coated. The present invention addresses this limitation by providing a system comprising a plurality of independently operable components (i.e., transfer and process chambers, load lock chambers, etc.), where each process chamber is configured to perform one or more steps in a process. This allows for sets of parts to be independently biased, which enables the system to simultaneously coat each set of parts via a designated coating process (i.e., unique to each set). Thus, coating properties may be individually controlled for each set of parts being simultaneously processed. The design of the system also makes the coating of parts of multiple geometries possible, as well as the shutting down of individual chambers (e.g., for preventative and repair maintenance) without interrupting production capacity. Further, as each process chamber may be configured to execute one or more steps in a process, the present system is able to perform processes having varying process step lengths.

Moreover, since the entire system is under vacuum pressure, the present system: minimizes or eliminates cross contamination; minimizes exposure to the atmosphere and variation in the environment caused by the venting and pumping cycles for associated with traditional batch coaters; and makes the operation and maintenance of each chamber simplified, predictable, and repeatable, which results in a higher yield (a major cost center in high-volume man manfacturing). All process and transfer chambers may also be kept at an independently controlled constant temperature. This eliminates thermal cycling, which combined with venting and exposure to the atmosphere, are the main contributors to debris generation and an increase in the frequency of preventative maintenance. In the present invention, all pump and vent cycles are confined to the load lock chambers, where no deposition, and therefore no byproduct accumulation, occurs. In some embodiments of the present invention, the temperature of each process chamber is held at a constant temperature appropriate for that process step. In other words, all thermal cycling may be confined to the parts and carriers going through the one or more processes. Shedding of coating as a result of thermal cycling, exposure to the atmosphere, and coating over coating are thus greatly reduced; resulting in a reduction of required preventative maintenance.

### DEFINITIONS

As used herein, the term “in-line vaccum processing system” or “in-line coating system” refers to a system for processing parts (or alternately, substrates), where pre-processing and processing steps are performed by components disposed in a single line. The offset system of the present invention provides components that may be in-line and/or branched off of a main line (although various geometries, (e.g., a ring) are also possible, as will be subsequently discussed).

As used herein, the term “carrier” refers to a component for holding a plurality of parts to be coated by a processing system. The carrier may alternately be referred to as a carousel, as the carrier is typically rotatable.

As used herein, the term “process chamber” refers to a vacuum chamber within which a process (e.g., coating, cleaning, etc.) is performed on the parts disposed on a carrier.

As used herein, the term “transfer chamber” refers to a vacuum chamber configured to accept and transport a carrier. The transfer chamber of the present invention is able to both rotate a carrier and move a carrier in the x, y, and z directions.

As used herein, the term “individually biased” is defined as independently applying a voltage (or pulsed voltage) to each carrier. This enables the present system to utilize different voltages (or pulsed voltage waveforms) and levels (e.g., magnitudes) suitable to a given process chamber.

### BRIEF DESCRIPTION OF THE DRAWINGS

The features and advantages of the present invention will become apparent from a consideration of the following detailed description presented in connection with the accompanying drawings in which:

FIG. 1 shows a flow chart of an embodiment of the present invention.

FIG. 2 shows an embodiment of a carrier in accordance with the present invention.

FIG. 3 shows an embodiment of the interior of the carrier.

FIG. 4 shows a sectional view of an embodiment of the carrier.

FIG. 5 shows an overview of the offset in-line vacuum processing system of the present invention.

FIG. 6 is an illustration of an embodiment of process chamber in accordance with the present system.

FIG. 7 is an illustration of another embodiment a process chamber in accordance with the present system.

FIG. 8 shows a coating center layout an exemplary embodiment of the present invention having continuous carrier loading.

### DETAILED DESCRIPTION OF THE INVENTION

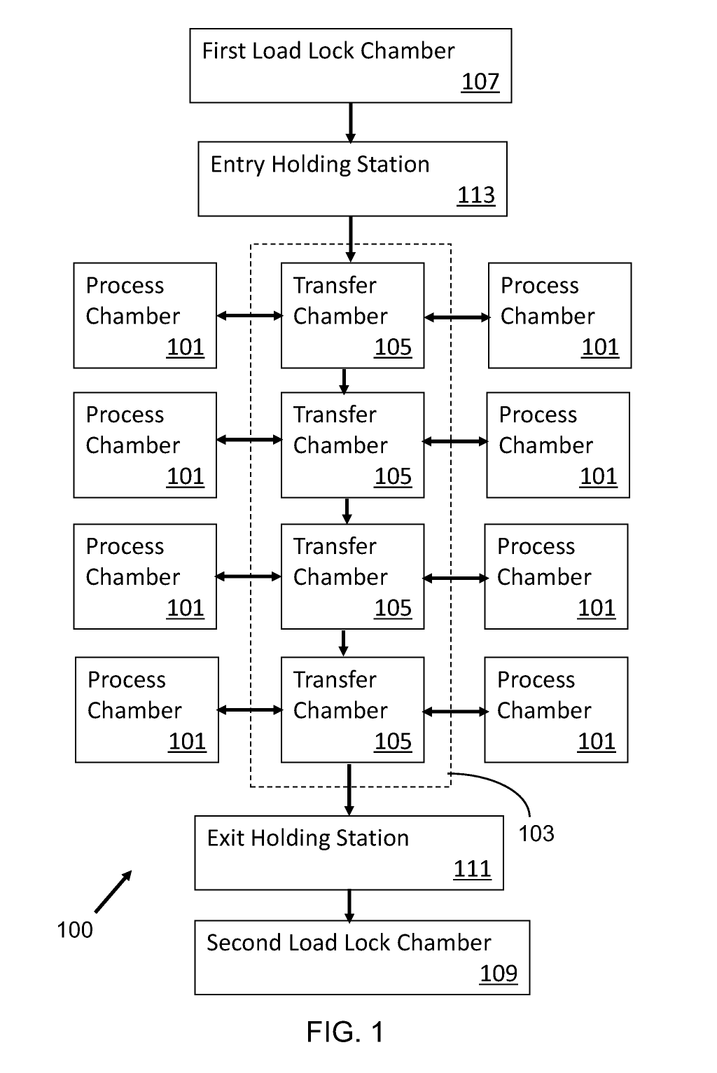

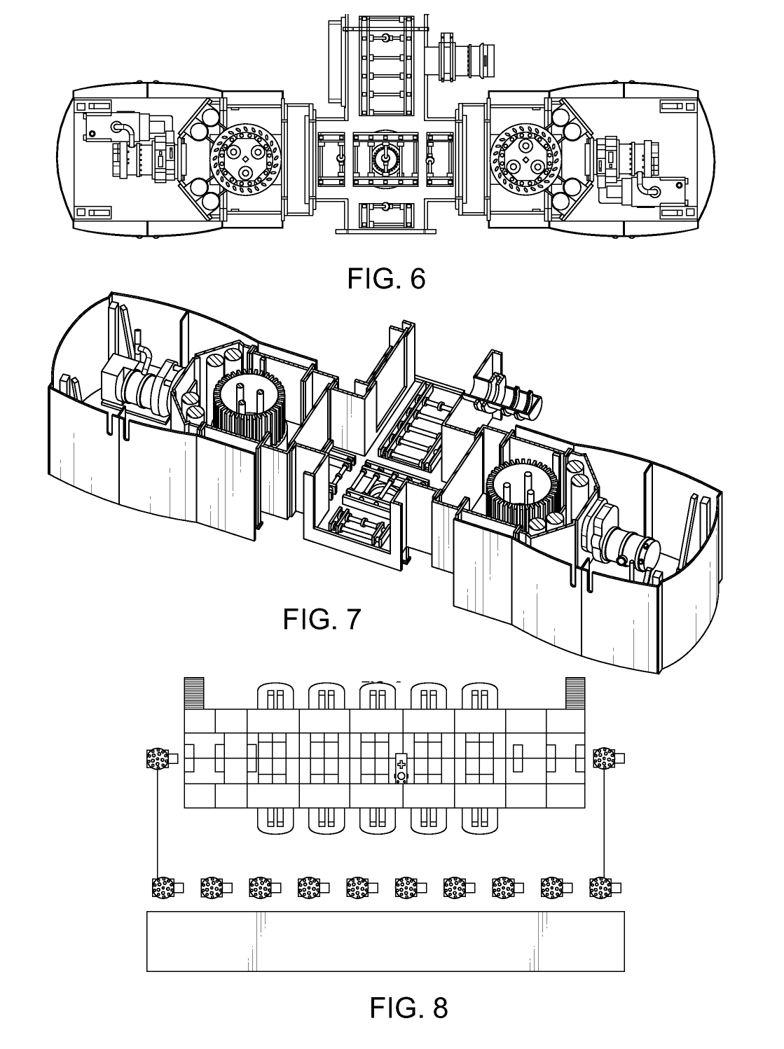

Referring now to FIGS. 1-8, the present invention features an offset, in-line vacuum processing system (100). In some embodiments, the system (100) comprises a plurality of process chambers (101) and a transfer station (103) comprising a plurality of independently operable transfer chambers (105). In other embodiments, each process chamber is configured to accommodate a given number of carriers that each hold a set of substrates. In an embodiment, each set of substrates are independently biased. In another embodiment, each process chamber is independently operable, held at vacuum pressure under independent pressure control, and configured to execute one or more steps in one or more processes performed on each set of substrates.

In further embodiments, the transfer station (103) comprises a plurality of independently operable transfer chambers (105) that are collectively pressure controlled at vacuum pressure. In one embodiment, each transfer chamber is operatively connected to one or more other transfer chambers and to one or more process chambers.

Consistent with previous embodiments, one or more carriers are initially loaded into a first transfer chamber. Each carrier may be routed through its own designated sequence of process chambers for performing a designated process, of the one or more processes. Further, the plurality of transfer chambers may be configured to transfer each carrier to and from each process chamber in the assigned designated sequence of process chambers. In exemplary embodiments, each set of substrates is independently biased; thus, each designated process may be individually tailored for a given set of carriers. The system (100) is therefore able to uniquely and independently process each set of substrates.

To illustrate, when a coating process is being performed, the system (100) is capable of coating each set of substrates with a unique coating exhibiting desired coating properties. Moreover, since each set of substrates may be independently and simultaneously processed, the system (100) is able to simultaneously coat substrates having differing geometries, (where each set of substrates has a common geometry and biased according to said geometry). Examples of the one or more processes performed by the system (100) include, but are not limited to: a heating process, a cleaning process, a cooling process, a coating process, or any process for preparing substrates for coating.

In some embodiments, the system (100) further comprises a first load lock chamber (107) and an entry holding station (113). In an embodiment, the entry holding station (113) operatively couples the first transfer chamber to the first load lock chamber (107). In a further embodiment, the one or more carriers are loaded into the first load lock chamber (107). In still other embodiments, the entry holding station (113) is configured to accept the one or more carriers from the first load lock chamber (107), optionally hold said carriers for a determined time period, and transmit the carriers to the first transfer chamber. In preferred embodiments, the entry holding station (113) and the first load lock chamber (107) are each independently operable and held at vacuum pressure under independent pressure control.

In additional embodiments, an independently operable exit holding station (111) operatively couples a last transfer chamber of the transfer station (103) to an independently operable second load lock chamber (109). In preferred embodiments, each carrier is moved to the last transfer chamber after the designated process is complete and subsequently transferred to the exit holding station (111) to cool down for a predetermined time. Each carrier may then exit the system (100) via the second load lock chamber (109).

In a supplementary embodiment, the process time of each process chamber in the designated sequence is the same. In an alternate embodiment, each process chamber in the designated sequence has an individual process time, where the individual process time of at least one of said process chambers is different than that of the remaining process chambers. Each transfer chamber may be further configured to hold the one or more carriers for a predetermined time or until the individual process time of the next process chamber has expired.

In exemplary embodiments, the plurality of process chambers is categorized by function. Examples of these categories include, but are not limited to: cleaning, baking, depositing a base or subsequent layers, etc. In further embodiments, a number of process chambers of a given category are selected to maximize a production capacity of the system based on the individual process times.

In some embodiments, each process chamber, each transfer chamber, the entry holding station (113), the exit holding station (111), and the first and second load lock chambers (107,109) have a carrier capacity for holding a designated number of carriers.

The present invention additionally features, an offset in-line vacuum processing system (100) for simultaneously processing substrates, having a common geometry or differing geometries, via one or more processes. In some embodiments, the system (100) comprises: a plurality of process chambers (101) each configured to accommodate a given number of carriers that each hold a set of substrates; a transfer station (103) comprising a plurality of transfer chambers (105) that are collectively pressure controlled at vacuum pressure; a first load lock chamber (107) held at vacuum pressure under independent pressure control; an entry holding station (113) held at vacuum pressure under independent pressure control and operatively coupling the first transfer chamber of the transfer station (103) to the first load lock chamber (107); an exit holding station (111) operatively coupled to the last transfer chamber of the transfer station (103); and a second load lock chamber (109) operatively coupled to the exit holding station (111). In preferred embodiments, each process chamber, each transfer station, the first and second load lock chambers (107,109), and the entry and exit holding stations (113,111) are all independently operable.

In an embodiment, each set of substrates are independently biased. In another embodiment, each process chamber is configured to execute one or more steps in the one or more processes performed on each set of substrates. In still other embodiments, each transfer chamber is operatively coupled to one or more other transfer chambers and to one or more process chambers.

Consistent with previous embodiments, one or more carriers are loaded into the first load lock chamber (107). In some embodiments, the entry holding station (113) accepts the one or more carriers from the first load lock chamber (107), optionally holds said carriers for a determined time period, and transmits the carriers to the first transfer chamber. Each carrier may then be routed from the first transfer chamber through its own designated sequence of process chambers for performing a designated process, of the one or more processes. Further, the plurality of transfer chambers may be configured to transfer each carrier to and from each process chamber in the assigned designated sequence of process chambers. In exemplary embodiments, each set of substrates is independently biased; thus, each designated process may be individually tailored for a given set of carriers. The system (100) is therefore able to uniquely and independently process each set of substrates.

To illustrate, when a coating process is being performed, the system (100) is capable of coating each set of substrates with a unique coating exhibiting desired coating properties. Moreover, since each set of substrates may be independently and simultaneously processed, the system (100) is able to simultaneously coat substrates having differing geometries, (where each set of substrates has a common geometry and biased according to said geometry). Examples of the one or more processes performed by the system (100) include, but are not limited to: a heating process, a cleaning process, a cooling process, a coating process, or any process for preparing substrates for coating.

In a supplementary embodiment, the process time of each process chamber in the designated sequence is the same. In an alternate embodiment, each process chamber in the designated sequence has an individual process time, where the individual process time of at least one of said process chambers is different than that of the remaining process chambers. Each transfer chamber may be further configured to hold the one or more carriers for a predetermined time or until the individual process time of the next process chamber has expired.

In exemplary embodiments, the plurality of process chambers is categorized by function. Examples of these categories include, but are not limited to: cleaning, baking, depositing a base or subsequent layers, etc. In further embodiments, a number of process chambers of a given category are selected to maximize a production capacity of the system based on the individual process times.

In some embodiments, each process chamber, each transfer chamber, the entry holding station (113), the exit holding station (111), and the first and second load lock chambers (107,109) have a carrier capacity for holding a designated number of carriers.

The present invention further features a method for simultaneously processing a plurality of substrates having differing geometries via one or more processes. In exemplary embodiments, the method comprises providing an offset in-line vacuum processing system (100) comprising: a plurality of process chambers (101) each configured to accommodate a given number of carriers that each hold a set of substrates; a transfer station (103) comprising a plurality of transfer chambers (105) that are collectively pressure controlled at vacuum pressure; a first load lock chamber (107) held at vacuum pressure under independent pressure control; an entry holding station (113) held at vacuum pressure under independent pressure control and operatively coupling the first transfer chamber of the transfer station (103) to the first load lock chamber (107); an exit holding station (111) operatively coupled to the last transfer chamber of the transfer station (10); and a second load lock chamber (109) operatively coupled to the exit holding station (111). In preferred embodiments, each process chamber, each transfer station, the first and second load lock chambers (107,109), and the entry and exit holding station (113, 111) are all independently operable.

In an embodiment, each set of substrates are independently biased. In another embodiment, each process chamber is configured to execute one or more steps in the one or more processes performed on each set of substrates. In still other embodiments, each transfer chamber is operatively coupled to one or more other transfer chambers and to one or more process chambers.

The method may further comprise:
loading one or more carriers into the first load lock chamber (107), where the entry holding station (113) accepts the one or more carriers from the first load lock chamber (107), optionally holds said carriers for a determined time period, and transmits the carriers to the first transfer chamber;
routing each carrier, from the first transfer chamber, through a designated sequence of process chambers for performing a designated process, of the one or more processes, wherein the plurality of transfer chambers is configured to transfer each carrier to and from each process chamber in the designated sequence;
moving each carrier is to the last transfer chamber after the designated process is complete;
transferring each carrier to the exit holding station (111) to cool down or a predetermined time; and
removing each carrier, holding a set of processed substrates, from the offset line vacuum processing system (100) via the second load lock chamber (109).

In additional embodiments, each set of substrates is independently biased; thus, each designated process may be individually tailored for a given set of carriers. The system (100) is therefore able to uniquely and independently process each set of substrates. To illustrate, when a coating process is being performed, the system (100) is capable of coating each set of substrates with a unique coating exhibiting desired coating properties.

Moreover, since each set of substrates may be independently and simultaneously processed, the system (100) is able to simultaneously coat substrates having differing geometries, (where each set of substrates has a common geometry and biased according to said geometry). Examples of the one or more processes performed by the system (100) include, but are not limited to: a heating process, a cleaning process, a cooling process, a coating process, or any process for preparing substrates for coating.

In a supplementary embodiment, the process time of each process chamber in the designated sequence is the same. In an alternate embodiment, each process chamber in the designated sequence has an individual process time, where the individual process time of at least one of said process chambers is different than that of the remaining process chambers. Each transfer chamber may be further configured to hold the one or more carriers for a predetermined time or until the individual process time of the next process chamber has expired.

In exemplary embodiments, the plurality of process chambers is categorized by function. Examples of these categories include, but are not limited to: cleaning, baking, depositing a base or subsequent layers, etc. In further embodiments, a number of process chambers of a given category are selected to maximize a production capacity of the system based on the individual process times.

In some embodiments, each process chamber, each transfer chamber, the entry holding station (113), the exit holding station (111), and the first and second load lock chambers (107,109) have a carrier capacity for holding a designated number of carriers.

As may be understood by one of ordinary skin in the art, the systems of the present disclosure may take on various geometries. As a non-limiting example, the transfer station (103) may be longitudinal in geometry having the plurality of process chambers (101) branching out along either longitudinal side of the transfer station (103) as seen in FIG. 1. As another non-limiting example, the plurality of process chambers (101) may form a ring around a central transfer station (103). Other possible geometries include any polygonal shape having the transfer station (103) as a central transfer arm and/or incorporated into the outline of the polygonal shape formed.

Moreover, the transfer station (103) of any of the present systems may comprise one or more transfer chambers. Each transfer chamber may be connected to one or more processing chambers and/or to one or more other transfer chambers. Non-limiting examples include, but are not limited to: one transfer chamber connected to three process chambers, one transfer chamber connected to one process chamber, two transfer chambers connected to one process chamber, and the like. As previously mentioned, the number of process chambers of a given type may be chosen to maximize a production capacity of the system based on the individual process times.

Further, the systems of the present invention are modular, as each component is independently operable, and configurable for maximizing production.

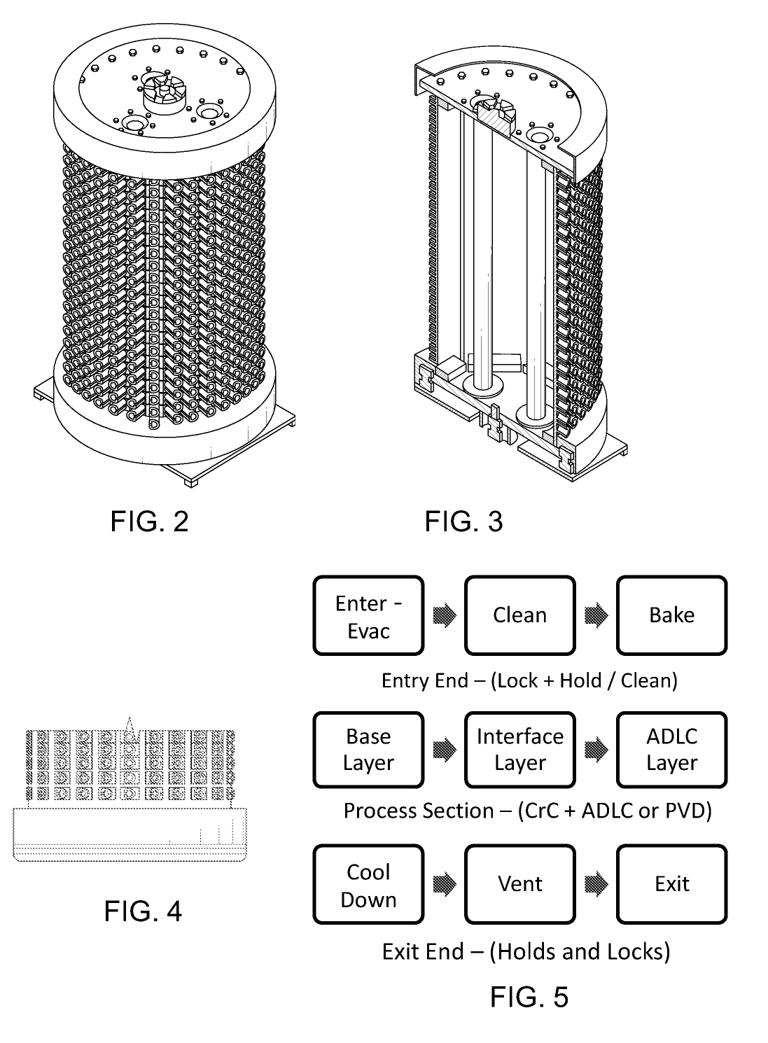

The one or more carriers may each be a rotating carousel. Additionally, the one or more carriers may be continuously supplied and/or loaded into the system. Said loading may be in a clean room environment or in a separate mating room. An embodiment of the carriers is shown in FIGS. 2-4. In this embodiment, the individual stringers disposed on the exterior of the carrier are configurable (e.g., to allow for various sizes). The carrier also limits debris and chamber maintenance and features high density second rotation fixtures.

The systems of the present disclosure may be configured to perform a variety of processes including, but not limited to: chemical vapor deposition (“CVD”), plasma enhanced chemical vapor deposition (“PECVD”), PECVD via a plasma beam source (“PBS”), physical vapor deposition (“PVD”), cathodic arc evaporation (“CAE”), and the like. The following provides non-limiting details of the above referenced process types and components of the present systems.

### System Details

### PVD Chamber Details

The system may utilize a series of PVD chambers, the number of which may be determined by the individual chamber throughput and the capacity demands of the application. The PVD process chamber may comprise:
a chamber with a capacity for a single loaded carrier;
heaters and associated temperature monitoring and control hardware;
a system of rails, mechanical stops, and motors to: accept a new carrier, rotate and bias the carrier during deposition, and to move the carrier back to the transfer station;
a large area, high-cycle, and high-vacuum gate valve sufficient for h passage of a loaded carrier (e.g., for a 1.2 m×2.2 m opening);
vacuum pumps with associated fore line tubes, exhaust gauges, pressure gauges, isolation valves, and bypass valves required to evacuate the chamber and monitor and control the process pressure;
a PVD source utilizing: two sets of dual rotary magnetron sources with associated power supplies, ARC evaporative targets, and planar magnetrons;
mass flow controllers with associated tubing and binary manifolds to deliver gases for sputtering and reactive sputtering; and
an independent power supply to bias substrates for controlling ion energy and coating properties.

### PECVD/PBS Chamber Details

The system may utilize a series of PBS chambers, the number of which may be determined by the individual chamber throughput and the capacity demands of the application. The PECVD/PBS chamber may comprise:
a camber with capacity for a single bladed carousel;
a system of rails, mechanical stops, and motors to: accept a new carrier, rotate and bias the carrier during deposition, and to move the carrier back to the transfer station;
a large area, high-cycle, and high-vacuum gate valve sufficient for passage f a loaded carrier (e.g., a 1.2 m×22 m opening);
vacuum pumps with associated fore line tubes, exhaust gauges, pressure gauges, isolation valves, and bypass valves required to evacuate the chamber and monitor and control the process pressure;
a PBS with associated radio-frequency (“RF”) power supply, matching network, and precursor delivery manifold;
mass flow controllers with associated tubing and manifolds to deliver precursors (with optional liquid delivery and evaporator for liquid precursors); and
an independent power supply to bias substrates for controlling ion coating properties.

### Transfer Station Details

The system may utilize a series of transfer stations, with the quantity dictated by the number of process chambers (e.g., a smaller version may have three while larger configurations may have six or more). Each transfer chambers able to rotate and move carriers in the x, y, and a directions. Each transfer station may comprise:
transfer chamber(s) with a capacity for specified number of carousels required to “feed” the attached chambers and configuration (e.g., load, clean, PVD, PECVD, hold):
a system of rails,mechanical stops, and motors to accept a new carrier and to move and/or rotate the carrier loaded with parts to next stations (next process chamber, transfer position, or to the holding stations);
large area, high-cycle, and high-vacuum gate valves sufficient for passage of a loaded carrier (e.g., a 1.2 m×2.2 m opening) are contributed by the attached chambers and make up part of the vacuum isolation system;
vacuum pumps with associated fore line tubes, exhaust gauges, pressure gauges, isolation valves, and bypass valves required to evacuate the chamber and monitor the process pressure;

### Holding Station Details

The holding station may be a vacuum and cooling chamber. The present systems may utilize the holding stations to allow substrates to cool slowly for minimizing stress in the substrates. The holding station may comprise:
a chamber with a capacity for a specified number of carriers to allow for a cooling time sufficient said capacity (e.g., a small configuration may have a capacity of two while larger systems may have a capacity for 3 or more carriers);
a system of rails, mechanical stops, and motors to: accept a new carrier and to move and/or rotate the carrier loaded with parts to the next stations or to the exit load lock station;
a large area, high-cycle, and high-vacuum gate valve sufficient for passage of a loaded carrier (e.g., a 1.2 m×2.2 m opening), where another gate valve is contributed by the exit load lock; and
vacuum pumps with associated fore line tubes, exhaust gauges, pressure gauges, isolation valves, and bypass valves required to evacuate the chamber and monitor the process pressure.

### Load Lock Chamber Details

The present systems may utilize two load lock chambers: one for parts to enter the vacuum system and one for coated parts to depart the vacuum system. Each load lock chamber may have a given carrier capacity and may comprise:
a system of rails, mechanical stops, and motors to: accept a new carrier and to move the carrier loaded with substrates to the transfer area;
two (entry from atmosphere and exit to transfer) large-area, high-cycle, and high-vacuum gate valves sufficient for passage of a loaded carder (e.g., for a 1.2 m×2.2 m opening);
vacuum pumps with associated pressure gauges,isolation valve, and bypass valves required to evacuate the chamber and monitor pressure;
a vent valve and a supply of clean dry al nitrogen):
an associated fore line and exhaust piping; and
associated power and controls (including carrier position monitoring, etc.).

Moreover, each gate valve included in the detailed chambers may be self-monitoring, intrinsically safe, smart valves. Additionally, each carrier may be coupled to a supervisory control and data acquisition (“SCADA”) control system, which determines when a process violation is occurring. For example, the SCADA control system may utilize metrological principles to monitor the state of mechanical parts employed in each chamber. In some embodiments, in-process location metrology is employed to trace the faulty mechanical part of a chamber. In these embodiments, any carriers disposed inside the chamber may be swiftly removed and the chamber may be shut down for needed repairs. As previously detailed, the operation of remaining chambers in the present system would remain undisturbed by said shut down. These procedures allow for coating processes to be executed safely.

Further, bias separation/isolated process chambers r employed to enable processes with varying bias requirements to occur simultaneously in different process chambers. For instance, a base layer may be deposited on a substrate at one bias voltage and waveform in one chamber, while a plasma dean is performed at a different bias voltage with a different waveform in a different chamber. Further, a hard coating may be deposited on top of the base layer in a third chamber using a third combination of bias voltage and timing. This can be extrapolated to any number of chambers and processes.

TABLE 1
Comparison of the system characteristics of the Present Offset In-
Line Coating System vs. Batch and Classic In-Line Coating Systems

| Offset In-Line | Batch and Classic In-Line |
|---|---|
| Thin or Thick Film (Technical) | Thin Film |
| Micron Rates | Nanometer Rates |
| Multi-Layer | Multi-Layer |
| Enables Cathode Tech | Matches Cathode Tech |
| | Does Not Match Technical Tech |
| Staged Line Speed | Continuous Line Speed |
| Enables Variable Film Growth | Matches Film Growth Rates |
| Rate | |
| Excellent Throughput | Excellent Throughput |
| Lowers Risk of Loss with | Risk of Loss of Coater Load |
| Offset Process Load from | from Mechanical Problems |
| Mechanical Problems | |
| Long Run Times | Long Run Times |
| Near Infinite Run Times Possible | Run Time Matched to Target Life |
| Live Process Maintenance Enables | and or Debris Shield Effective Life |
| Continuous Uptime | Tried and True Controls, Vacuum, |
| Control, Vacuum, and Drive | and Drive Systems |
| Systems Designed with Excellent | |
| Risk Mitigation Plan | |
| Uptime Critical | Uptime Critical |
| Near 100% Uptime | Annual Uptime Critical |
| Loss of ANY Chamber and/or | for Profitability |
| Zone | |
| Does Not Result in Coater Load | High Probability of Coater Load |
| Loss | Loss Due to Zone Failure |
| Modular and Uptime Design Goals | High Probability of Coater Restarts |
| Ensure Access and Ease of Zone | Required for Zone Failures |
| Repair | |
| Maintenance | Maintenance |
| Planned | Time Based |
| No Loss of Entire Coater Availability | Loss of Entire Coater Availability |
| Reduced Potential for Human Error | Human Error Results in Prolonged |
| due to Simplified Process Zone | Loss of Availability |
| Target Utilization Costs | Target Utilization Costs |
| Rotary Based | Rotary Based |
| Optimized for Thin and Thick Films | Optimized for Thin Film |
| Enables Extreme Long Run Times | Enables Long Run Times |
| Design Enables Low Cathode to | Not Optimized for Thick Films |
| Part Ratio | |
| Full PVD/ADLC Functionality | Non PVD/ADLC Functionality |
| Purposely Built for PVD/DLC Films | PVD/ADLC Not Traditional to In- |
| Full Carrier Bias Functionality | Line Class of Equipment (Except |
| Variable Biasing of Carriers is | Solar) |
| Standard | Difficulty Carrier Bias |
| | Functionality |
| | Variable Biasing of Carriers |
| | Difficult |
| | and Results in More Required |
| | Cathodes |
| Capital Costs | Capital Costs |
| Low CAPEX per Part | Low CAPEX per Part |
| Reduced Foot Print Enables Lower | Higher Facility Costs (Foot Print) |
| Facility Costs | |
| Reduced Foot Print Enables | |
| Flexible Installation Locations | |
| Product Configurability | Product Configurability & |
| Multiple Products Per Cycle | Implementation |
| Designed Capacity Enables Live | Single Product Per Cycle |
| Recipe Installation | Off-line or Dedicated Coater |
| | Use (and Loss of Availability of |
| | Coater) for New Process |
| | Implementation |
| Tailored Throughput | Fixed Throughput |
| Product Class and Type are | Designed for Specific Range of |
| Configurable | Coatings for Large Area |
| Resulting Machine Foot Print is | Substrates |
| Considerably Smaller | Resulting Machine Foot Print and |
| Tailored Configurations to Match | Facility Capex Costs are High |
| Source Part Volume Enables | |
| Smaller Machine Foot Print and | |
| Capex Costs | |
| Product Traceability | Product Traceability |
| Intelligent Part Loading and Coater | Batch or Post Run Data Metrics |
| Tracking of Every Carousel | Only |
| Enables Live Metrology of | Limited Metrology Per Individual |
| Representative Part Temperature | Part |
| Test Carriers Enable Rate | |
| Monitoring and Other R&D | |
| Capabilities | |
| Quality (Film) | Quality (Film) (Batch) |
| Inherent Stability and control of | Inherent Variability in Debris, |
| Debris, Pressure, Partial | Pressure, Partial Pressures, and |
| Pressures, and Temperature due | Temperature due to Cycle Type |
| to Cycle Type | |

As used herein, the term “about” refers to plus or minus 10% of the referenced number.

Various modifications of the invention, in addition to those described herein, will be apparent to those skilled in the art from the foregoing description. Such modifications are also intended to fall within the scope of the appended claims. Each reference cited in the present application is incorporated herein by reference in its entirety.

Although there has been shown and described the preferred embodiment of the present invention, it will be readily apparent to those skilled in the art that modifications may be made thereto which do not exceed the scope of the appended claims. Therefore, the scope of the invention is only to be limited by the following claims. Reference numbers recited in the claims are exemplary and for ease of review by the patent office only, and are not limiting in any way. In some embodiments, the figures presented in this patent application are drawn to scale, including the angles, ratios of dimensions, etc. In some embodiments, the figures are representative only and the claims are not limited by the dimensions of the figures. In some embodiments, descriptions of the inventions described herein using the phrase “comprising” includes embodiments that could be described as “consisting of”, and as such the written description requirement for claiming one or more embodiments of the present invention using the phrase “consisting of” is met.

The reference numbers recited in the below claims re solely for ease of examination of this patent application, and are exemplary, and are not intended in any way to limit the scope of the claims to the particular features having the corresponding reference numbers in the drawings.

1. An offset in-line vacuum processing system (100) comprising:
(a) a plurality of process chambers (101) each configured to accommodate a given number of carriers that each hold a set of substrates, wherein each set of substrates are independently biased, wherein each process chamber is independently operable, held at vacuum pressure under independent pressure control, and configured to execute one or more steps in one or more processes performed on each set of substrates; and
(b) a transfer station (103) comprising a plurality of independently operable transfer chambers (105) that are collectively pressure controlled at vacuum pressure, wherein each transfer chamber is operatively coupled to one or more other transfer chambers and to one or more process chambers,
wherein one or more carriers are loaded into a first transfer chamber, of the plurality of transfer chambers (101), wherein each carrier is routed through a designated sequence of process chambers for performing a designated process, of the one or more processes, wherein the plurality of transfer chambers is configured to transfer each carrier to and from each process chamber in the designated sequence,
wherein, as each set of substrates is independently biased and subject to only the designated process, the system (100) is able to uniquely and independently process each set of substrates.

2. The system (100) of claim 1, wherein the one or more processes comprises a heating process, a cleaning process, a cooling process, or a coating process.

3.-8. (canceled)

9. The system (100) of claim 1 further comprising a first load lock chamber (107) that is held at vacuum pressure under independent pressure control and operatively coupled to the first transfer chamber of the transfer station (103), wherein the first load lock chamber is (107) independently operable, wherein the one or more carriers are loaded into the first transfer chamber via the first load lock chamber (107).

10. The system (100) of claim 9, wherein an entry holding station (113) operatively couples the first transfer chamber of the transfer station (103) and the first load lock chamber (107), wherein the entry holding station (113) accepts the one or more carriers from the first load lock chamber (107), optionally holds said carriers for a determined time period, and transmits the carriers to the first transfer chamber, wherein the entry holding station (113) is independently operable and held at vacuum pressure under independent pressure control.

11. The system (100) of claim 10 further comprising an exit holding station (111) and a second load lock chamber (109), wherein the exit holding station (111) operatively couples a last transfer chamber and the second load lock chamber (109), wherein the exit holding station (111) and the second load lock chamber (109) are each independently operable, wherein each carrier is moved to the last transfer chamber after the designated process is complete and subsequently transferred to the exit holding station (111) to cool down for a predetermined time, wherein each carrier then exits the system (100) via the second load lock chamber (109).

12. An offset, in-line vacuum processing system (100) for simultaneously processing substrates, having a common geometry or differing geometries, via one or more processes, said system (100) comprising:
a. a plurality of process chambers (101) each configured to accommodate a given number of carriers that each hold a set of substrates, wherein each set of substrates are independently biased, wherein each process chamber is independently operable, held at vacuum pressure under independent pressure control, and configured to execute one or more steps in the one or more processes performed on each set of substrates;
b. a transfer station (103) comprising a plurality of independently operable transfer chambers (105) that are collectively pressure controlled at vacuum pressure, wherein each transfer chamber is operatively coupled to one or more other transfer chambers and to one or more process chambers;
c. a first load lock chamber (107) that is independently operable and held at vacuum pressure under independent pressure control;
d. an entry holding station (113) that operatively couples a first transfer chamber of the transfer station (103) and the first load lock chamber (107), wherein the entry holding station (113) is independently operable and held at vacuum pressure under independent pressure control;
e. an exit holding station (111) that is independently operable and held at vacuum pressure under independent pressure control, wherein the exit holding station (111) is operatively coupled to a last transfer chamber of the transfer station (103); and
f. a second load lock chamber (109) that is independently operable and held at vacuum pressure under independent pressure control, wherein the second load lock chamber (109) is operatively coupled to the exit holding station (111),
wherein one or more carriers are loaded into the first load lock chamber (107), wherein the entry holding station (113) accepts the one or more carriers from the first load lock chamber (107), optionally holds said carriers for a determined time period, and transmits the carriers to the first transfer chamber,
wherein each carrier is routed through a designated sequence of process chambers for performing a designated process, of the one or more processes, wherein the plurality of transfer chambers is configured to transfer each carrier to and from each process chamber in the designated sequence,
wherein each carrier is moved to the last transfer chamber after the designated process is complete and subsequently transferred to the exit holding station (111) to cool down for a predetermined time, wherein each carrier then exits the system (100) via the second load lock chamber (109),
wherein each set of substrates is capable of being independently biased as each set is subject only to the designated process, wherein the system (100) is thus able to individually process each set of substrates whether having the common geometry or differing geometries, wherein each of the plurality of process and transfer chambers can be independently taken offline without affecting remaining process and transfer chambers as each are independently operable.

13. The system (100) of claim 12, wherein the one or snore processes comprises a heating process, a cleaning processor, a cooling process, or a coating process.

14. The system (100) of claim 13, wherein each set of substrates is coated, according to the coating process, with a unique coating exhibiting desired coating properties.

15. The system (100) of claim 12, wherein the process time of each process chamber in the designated sequence is the same.

16. The system (100) of claim 12, wherein each process chamber in the designated sequence has an individual process time, wherein the individual process time of at least one of said process chambers is different than that of remaining process chambers.

17. The system (100) of claim 16, wherein each transfer chamber is further configured to hold the one or more carriers for a predetermined time or until the individual process time of the next process chamber has expired.

18. The system (100) of claim 16, wherein the plurality of process chambers is categorized by function, wherein a number of process chambers of a given category are selected to maximize a production capacity of the system based on the individual process times.

19. (canceled)

20. A method for simultaneously processing a plurality of substrates having differing geometries via one or more processes, said method comprising:
a. providing an offset in-line vacuum processing system (100) comprising:
i. a plurality of process chambers (101) each configured to accommodate a given number of carriers that each hold a set of substrates, wherein each set of substrates are independently biased, wherein each process chamber is independently operable, held at vacuum pressure under independent pressure control, and configured to execute one or more steps in the one or more processes performed on each set of substrates;
ii. a transfer station (103) comprising a plurality of independently operable transfer chambers (105) that are collectively pressure controlled at vacuum pressure, wherein each transfer chamber is operatively coupled to one or more other transfer chambers and to one or more process chambers;
iii. a first load lock chamber (107) that is independently operable and held at vacuum pressure under independent pressure control;
iv. an entry holding station (113) that operatively couples a first transfer chamber of the transfer station (103) and the first load lock chamber (107), wherein the entry holding station (113) is independently operable and held at vacuum pressure under independent pressure control;
v. an exit holding station (111) that is independently operable and held at vacuum pressure under independent pressure control, wherein the exit holding station (111) is operatively coupled to a last transfer chamber of the transfer station (103); and
vi. a second load lock chamber (109) that is independently operable and held at vacuum pressure under independent pressure control, wherein the second load lock chamber (109) is operatively coupled to the exit holding station (111);
b. loading one or more carriers into the first load lock chamber (107), wherein the entry holding station (113) accepts the one or more carriers from the first load lock chamber (107), optionally holds said carriers for a determined time period, and transmits the carriers to the first transfer chamber;
c. routing each carrier through a designated sequence of process chambers for performing a designated process, of the one or more processes, wherein the plurality of transfer chambers is configured to transfer each carrier to and from each process chamber in the designated sequence;
d. moving each carrier is to the last transfer chamber after the designated process is complete;
e. transferring each carrier to the exit holding station (111) to cool down for a predetermined time;
f. removing each carrier, holding a set of processed substrates, from the offset in-line vacuum processing system (100) via the second load lock chamber (109),
wherein each set of substrates is capable of being independently biased as each set is subject only to the designated process, wherein the system (100) is thus able to individually process each set of substrates having differing geometries, wherein each of the plurality of process and transfer chambers can be independently taken offline without affecting remaining process and transfer chambers as each are independently operable.

21. The method of claim 20, wherein the one or more processes comprises a heating process, a cleaning processor, a cooling process, or a coating process.

22. The method of claim 21, wherein each set of substrates is coated, according e coating process, with a unique coating exhibiting desired coating properties.

23. The method of claim 20, wherein the process time of each process chamber in the designated sequence is the same.

24. The method of claim 20, wherein each process chamber in the designated sequence has an individual process time, wherein the individual process time of at least one of said process chambers is different than that of remaining process chambers.

25. The method of claim 24, wherein each transfer chamber is further configured to hold the one or more carriers for a predetermined time or until the individual process time of the next process chamber has expired.

26. The method of claim 24, wherein the plurality of process chambers is categorized by function, wherein a number of process chambers of a given category are selected to maximize a production capacity of the offset in-line vacuum processing system (100) based on the individual process times.

27. The method of claim 20, wherein each process chamber, each transfer chamber, the entry holding station (113), the exit holding station (111), and the first and second load lock chambers (107,109) have a carrier capacity for holding a designated number of carriers.
